(19) United States
(12) Patent Application Publication
(10) Pub. No.: US 2024/0120901 A1
(43) Pub. Date: Apr. 11, 2024

(54) ACOUSTIC RESONATOR EXCITED IN THICKNESS SHEAR MODE

(71) Applicant: SPECTRON (SHENZHEN) TECHNOLOGIES CO., LTD, Shenzhen (CN)

(72) Inventors: Songbin GONG, Shenzhen (CN); Ruochen LV, Shenzhen (CN)

(21) Appl. No.: 18/275,304

(22) PCT Filed: Mar. 11, 2022
(86) PCT No.: PCT/CN2022/080450

§ 371 Date: Aug. 1, 2023

(30) Foreign Application Priority Data
Mar. 15, 2021 (CN) 202110276005.7
Mar. 15, 2021 (CN) 202120532330.0

(51) Int. Cl. H03H 9/17; H03H 9/13

(52) U.S. Cl. CPC H03H 9/175; H03H 9/132; H03H 9/133

(57) ABSTRACT

An acoustic resonator excited in a thickness shear modes includes an acoustic mirror, a bottom electrode layer, a piezoelectric layer, a top electrode unit, and transverse reflectors. The acoustic mirror comprises at least one first acoustic reflective layer and at least one second acoustic reflective layer, and the acoustic impedance of each first acoustic reflective layer is less than that of each second acoustic reflective layer. The bottom electrode layer is located on the acoustic mirror. The piezoelectric layer is provided on the bottom electrode layer. The top electrode unit is provided on the piezoelectric layer. The transverse reflectors are provided on the piezoelectric layer and comprises a first reflector located on the first side of the top electrode unit and a second reflector located on the second side of the top electrode unit, and the transverse reflectors are used for performing transverse reflection on the acoustic wave.

### CROSS-REFERENCE TO RELATED APPLICATIONS

This application is a National Stage for International Application PCT/CN2022/080450, filed on Mar. 11, 2022, which claims the priority benefit of Chinese Patent Application No. 2021102760057 filed on Mar. 15, 2021 and Chinese Patent Application No. 2021205323300 filed on Mar. 15, 2021. The entireties of both applications are incorporated by reference herein for all purposes.

### TECHNICAL FIELD

The present disclosure relates to the field of resonator technologies, and, in particular, to an acoustic resonator excited in a thickness shear mode.

### BACKGROUND

Radio frequency acoustic resonators are small structures used for filtering functions or as frequency sources. Acoustic resonators have replaced other types of resonators used in cell phones, small base stations, and Internet of Things (IoT) devices due to their smaller size and higher quality factor (Q). The acoustic resonators enable low loss (low power consumption), high rejection, high signal-to-noise ratio, and thinner packages.

With the release of new communication standards (i.e., fifth-generation mobile networks), it is necessary to extend the operating range of resonators to higher frequencies while maintaining high electromechanical coupling coefficients and high Q values.

### SUMMARY

According to various embodiments of the present disclosure, an acoustic resonator excited in a thickness shear mode is provided, including an acoustic mirror, a bottom electrode layer, a piezoelectric layer, a top electrode unit and transverse reflectors. The acoustic mirror includes at least one first acoustic reflective layer and at least one second acoustic reflective layer, and acoustic impedance of each first acoustic reflective layer is less than the acoustic impedance of each second acoustic reflective layer. The bottom electrode layer is arranged on the acoustic mirror. The piezoelectric layer is arranged on the bottom electrode layer. The piezoelectric layer includes at least one of single crystal lithium niobate or single crystal lithium tantalate. The top electrode unit is arranged on the piezoelectric layer. The reflectors is transverse to the acoustic mirror placed beneath the piezoelectric layer, and the transverse reflectors are also arranged on the piezoelectric layer. The transverse reflectors include a first reflector arranged on a first side of the top electrode unit and a second reflector arranged on a second side of the top electrode unit, the first side and the second side are opposite sides, and the transverse reflectors are configured to transversely reflect an acoustic wave. The bottom electrode layer and the top electrode unit are configured to apply an electric field.

In an embodiment, a direction of the electric field formed by the bottom electrode layer and the top electrode unit is substantially the same as a thickness direction of the piezoelectric layer, and the bottom electrode layer and the top electrode unit are further configured to generate a shear mode mechanical wave across a thickness of the entire piezoelectric layer.

In an embodiment, a thickness of the first acoustic reflective layer is positively proportional to a distance between the first acoustic reflective layer and the bottom electrode layer, and a thickness of the second acoustic reflective layer is positively proportional to a distance between the second acoustic reflective layer and the bottom electrode layer.

In an embodiment, the acoustic mirror includes three layers of the first acoustic reflective layer and two layers of the second acoustic reflective layer, and the first acoustic reflective layer and the second acoustic reflective layer in the acoustic mirror are arranged alternatively.

In an embodiment, a material of the first acoustic reflective layer includes at least one of silicon dioxide, aluminum, benzocyclobutene, polyimide or spin on glass, and a material of the second acoustic reflective layer includes at least one of molybdenum, tungsten, titanium, platinum, aluminum nitride, tungsten oxide or silicon nitride.

In an embodiment, the top electrode unit includes a first common electrode, a second common electrode, a plurality of first interdigital electrodes and a plurality of second interdigital electrodes. Each of the first interdigital electrodes is electrically connected to the first common electrode, each of the second interdigital electrodes is electrically connected to the second common electrode, and any of the first interdigital electrodes is insulated from any of the second interdigital electrodes.

In an embodiment, the acoustic resonator further includes a passivation layer arranged on the piezoelectric layer. The passivation layer covers each of the first interdigital electrodes and each of the second interdigital electrodes.

In an embodiment, a direction of a connecting line between the transverse reflectors on both sides of the top electrode unit is the same as a propagation direction of the acoustic wave. A width of the bottom electrode layer is smaller than a spacing between the first common electrode and the second common electrode, so that an orthographic projection of the bottom electrode layer on a plane where the top electrode unit is located is between the first common electrode and the second common electrode. Orthographic projections of each of the first acoustic reflective layers and each of the second acoustic reflective layers on the plane exceed the first reflector and the second reflector in the direction of the connecting line, respectively.

In an embodiment, the first reflector and the second reflector both include at least one electrode strip. A distance between the center of an electrode strip closest to the top electrode unit in the first reflector and the center of the interdigital electrode on an edge of the first side of the top electrode unit is equal to ⅛ to 2 wavelengths of the acoustic wave, and a distance between the center of the electrode strip closest to the top electrode unit in the second reflector and the center of the interdigital electrode on an edge of the second side of the top electrode unit is equal to ⅛ to 2 wavelengths of the acoustic wave.

In an embodiment, the acoustic resonator further includes a first metal structure arranged on the first common electrode and a second metal structure arranged on the second common electrode. Thicknesses of the first metal structure and the second metal structure are greater than a thickness of the top electrode unit respectively. The first metal structure and the second metal structure are used for acoustic reflection in a second direction, and the second direction is perpendicular to a propagation direction of the acoustic wave.

In an embodiment, an orthographic projection of each of the second acoustic reflective layers on a plane where the bottom electrode layer is located exceeds two sides of the bottom electrode layer in a first direction, or orthographic projections of each of the first acoustic reflective layers and each of the second acoustic reflective layers on the plane where the bottom electrode layer is located are covered by the bottom electrode layer respectively. The first direction is parallel to a propagation direction of the acoustic wave.

In an embodiment, a material of the top electrode unit is the same as the material of the transverse reflectors and is at least one of a metal or a metallic alloy.

In an embodiment, one of the at least one first acoustic reflective layer is closer to the bottom electrode layer than all of the second acoustic reflective layers.

In an embodiment, the acoustic resonator further includes a carrier wafer. The acoustic mirror is arranged on the carrier wafer.

In an embodiment, the acoustic resonator further includes a bonding auxiliary layer arranged between the carrier wafer and the acoustic mirror.

One or more embodiments of the present disclosure will be described in detail below with reference to drawings. Other features, objects and advantages of the present disclosure will become more apparent from the description, drawings, and claims.

### BRIEF DESCRIPTION OF THE DRAWINGS

In order to better describe and illustrate embodiments and/or examples of the present disclosure herein, one or more accompanying drawings may be referred. Additional details or examples used to describe the figures should not be considered limitations on the scope of any of the disclosure, the presently described embodiments and/or examples, and the presently understood best modes of the disclosure.

FIG. 1 is a top view of a portion of an acoustic resonator excited in a thickness shear mode according to an embodiment.

FIG. 2 is a cross-sectional view taken along the line A-A′ in FIG. 1.

FIG. 3 is a schematic diagram showing a propagation direction of an electric field and a propagation direction of a mechanical wave in a piezoelectric layer according to a proposed embodiment.

FIG. 4 is a schematic diagram showing a thickness of each reflective layer of an acoustic mirror according to an embodiment.

FIG. 5 is a schematic diagram showing a structure of a first reflector according to an embodiment.

FIG. 6 is a cross-sectional view taken along the line B-B′ in FIG. 1.

FIG. 7 is a schematic diagram of a distance Wg between the center of an electrode strip closest to a top electrode unit in a first reflector and the center of an interdigital electrode on an edge of a first side of the top electrode unit according to an embodiment.

FIG. 8 is a simulation result of a characteristic admittance of an acoustic resonator excited in a thickness shear mode according to an embodiment.

### DETAILED DESCRIPTION OF THE EMBODIMENTS

In order to facilitate understanding of the present disclosure, the present disclosure will be described more fully below with reference to the relevant accompanying drawings. Embodiments of the present disclosure are presented in the accompanying drawings. However, the present disclosure may be implemented in many different forms and is not limited to the embodiments described herein. Rather, these embodiments are provided for the purpose of making the present disclosure more thorough and comprehensive.

Unless otherwise defined, all technical and scientific terms used herein have the same meaning as commonly understood by those skilled in the technical field to which the present disclosure belongs. The terms used herein in the specification of the disclosure are for the purpose of describing specific embodiments only, and are not intended to limit the disclosure.

It should be understood that when an element or layer is referred to as being “on”, “adjacent”, “connected to”, or “coupled to” other elements or layers, it may be directly on, adjacent to, connected to, or coupled to other elements or layers, or there may be intervening elements or layers. Conversely, when the element is referred to as “directly on”, “directly adjacent to”, “directly connected”, or “directly coupled to” other elements or layers, there is no intervening elements or layers. It should be understood that although the terms first, second, third, etc. may be used to describe various elements, components, regions, layers and/or portions, these elements, components, regions, layers and/or portions should not be limited by these terms. These terms are used only to distinguish one element, component, region, layer or portion from another element, component, region, layer or portion. Accordingly, without departing from the teachings of this disclosure, the first element, component, region, layer or portion discussed below may be represented as a second element, component, region, layer or portion.

Spatial relational terms such as “beneath”, “below”, “underneath”, “under”, “on”, “above”, etc., may be used herein to describe the relationship of one element or feature to other elements or features shown in the figures. It should be understood that, in addition to the orientation depicted in the figures, the spatial relational terms further include different orientations of a device in use and operation. For example, if the device in the figures is turned over, elements or features described as “below” or “under” or “beneath” other elements or features would be oriented “above” the other elements or features. Thus, the exemplary terms “below” and “beneath” may include both above and below orientations. In addition, the device may also include additional orientations (e.g., rotation of 90 degrees or other orientations), and the spatial descriptors used herein interpreted accordingly.

As used herein, the singular forms “a”, “an” and “the” may also include the plural forms, unless the context clearly indicates otherwise. It should also be understood that the terms “includes/comprises” or “has” etc. designate the presence of stated features, integers, steps, operations, components, parts or combinations thereof, but do not preclude the possibility of the presence or addition of one or more other features, integers, steps, operations, components, parts or combinations thereof. Meanwhile, the term “and/or” as used herein includes any and all combinations of the relevant listed items in the present specification.

Bulk acoustic wave (BAW) and surface acoustic wave (SAW) resonators are the most commonly used devices for synthesizing filters and resonators between 0.6 GHz and 3 GHz. These acoustic devices are commercially successful and are widely used in mobile phone front-end modules or as discrete components in radio front-ends. Existing bulk acoustic wave and surface acoustic wave devices can achieve a Q value of more than 1000 and an electromechanical coupling coefficient of about 7%-10% at frequencies below 3 GHz. However, extending its frequency range above 3 GHz will encounter some technical uncertainties and physical limits. The new 5G standard requires the electromechanical coupling coefficient to be more than 10%, which cannot be achieved by the bulk acoustic wave and surface acoustic wave devices without changing the material or working mode of the bulk acoustic wave and surface acoustic wave devices. Likewise, material loss poses a fundamental limit to the maximum Q value achieved by conventional bulk acoustic wave and surface acoustic wave devices above 3 GHz.

In summary, the market needs new devices with a high electromechanical coupling and a high quality factor at frequencies above 3 GHz.

The present disclosure aims to provide a novel wafer-level mechanical/acoustic resonator capable of having a high Q value and a high electromechanical coupling coefficient at a frequency above 3 GHz. The resonator supports the synthesis of high-performance passband filters to meet the new requirements of 5G communication standards and future upgrades.

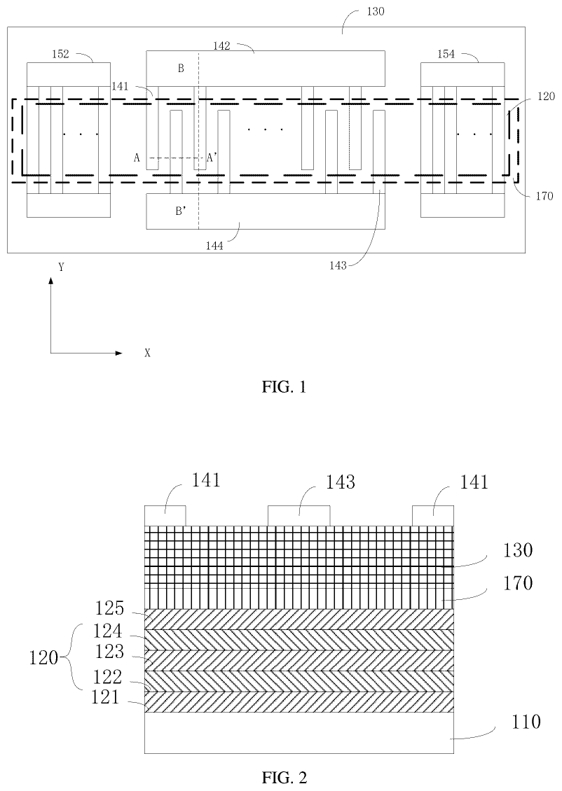

FIG. 1 is a top view showing a portion of an acoustic resonator excited in a thickness shear mode according to an embodiment, and FIG. 2 is a cross-sectional view taken along the line A-A′ in FIG. 1. Referring to FIGS. 1 and 2, the acoustic resonator excited in a thickness shear mode includes an acoustic mirror 120, a bottom electrode layer 170, a piezoelectric layer 130, a top electrode unit and transverse reflectors. FIG. 1 is primarily intended to illustrate the shapes of the top electrode unit and the transverse reflectors in corresponding embodiments, thereby omitting other structures on the piezoelectric layer 130.

The top electrode unit is arranged on the piezoelectric layer 130. The top electrode unit may include interdigital electrodes. In the embodiments shown in FIGS. 1 and 2, the top electrode unit includes a group of first interdigital electrodes 141 and a group of second interdigital electrodes 143. The first interdigital electrodes 141 and the second interdigital electrodes 143 extend in the Y direction in FIG. 1, so they are parallel to each other. Each first interdigital electrode 141 is insulated from each second interdigital electrode 143. The first interdigital electrode 141 is configured to receive an input voltage, and the second interdigital electrode 143 is configured for grounding. The top electrode unit further includes a first common electrode 142 and a second common electrode 144. One end of each first interdigital electrode 141 is connected to the first common electrode 142, and one end of each second interdigital electrode 143 is connected to the second common electrode 144. The common electrode is also called a bus bar.

The transverse reflectors are also arranged on the piezoelectric layer 130, and can be arranged on the same layer as the top electrode unit. The transverse reflectors include a first reflector 152 arranged on a first side (left side in FIG. 1) of the top electrode unit and a second reflector 154 arranged on a second side (right side in FIG. 1) of the top electrode unit. The transverse reflectors are insulated from the top electrode unit and configured to transversely reflect an acoustic wave.

The piezoelectric layer 130 is arranged on the bottom electrode layer 170. The piezoelectric layer 130 includes at least one of single crystal lithium niobate or single crystal lithium tantalate.

The bottom electrode layer 170 is arranged on the acoustic mirror 120. The bottom electrode layer 170 and the top electrode unit are configured to apply an electric field.

The acoustic mirror 120 includes at least one first acoustic reflective layer and at least one second acoustic reflective layer, and acoustic impedance of each first acoustic reflective layer is less than the acoustic impedance of each second acoustic reflective layer. In an embodiment of the present disclosure, the layer closest to the bottom electrode layer 170 in the acoustic mirror 120 should be the first acoustic reflective layer, i.e., there is one first acoustic reflective layer closer to the bottom electrode than all the second acoustic reflective layers 170. In the embodiment shown in FIG. 2, the acoustic mirror 120 includes three layers of first acoustic reflective layers (i.e., the first acoustic reflective layer 121, the first acoustic reflective layer 123, and the first acoustic reflective layer 125) and two layers of second acoustic reflective layers (i.e., the second acoustic reflective layer 122 and the second acoustic reflective layer 124), and each first acoustic reflective layer and each second acoustic reflective layer are arranged alternatively.

The above-mentioned acoustic resonator excited in a thickness shear mode generates the electric field by the top electrode unit and the bottom electrode layer, and the transverse reflectors transversely reflect the acoustic wave, so that the acoustic resonator can be excited in a shear vibration mode in the thickness direction. And because the piezoelectric layer is made of the single crystal lithium niobate or lithium tantalate, the acoustic resonator has a high electromechanical coupling coefficient and a high Q value at a frequency above 3 GHz.

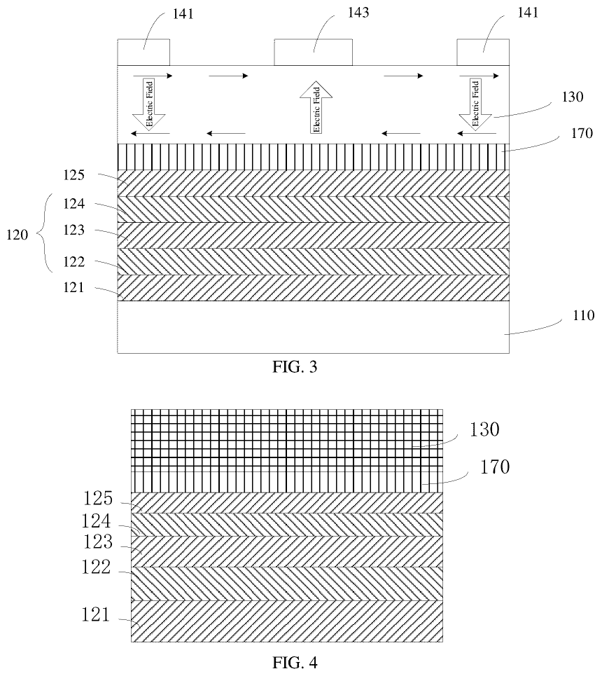

Referring to FIG. 3, the big arrow in the figure represents a direction of the electric field, the small arrow represents a propagation direction of a mechanical wave of the shear vibration mode, and the direction of the electric field is substantially the same as a thickness direction of the piezoelectric layer 130. The bottom electrode layer 170 and the top electrode unit are further configured to generate a shear mode mechanical wave across a thickness of the entire piezoelectric layer 130. The single crystal lithium niobate or lithium tantalate in combination with the top electrode unit structure and the transverse reflector structure of the present disclosure can obtain an optimized shear vibration mode. The optimized shear vibration mode has a greater acoustic wave velocity, and can reach higher frequencies than traditional commercial filters while the key dimensions (such as a spacing between fingers) of the device remain unchanged.

In an embodiment of the present disclosure, a material of the top electrode unit is the same as the material of the transverse reflector and is at least one of a metal or a metallic alloy. In an embodiment of the present disclosure, the top electrode unit can be made of aluminum (Al), copper (Cu), aluminum copper (AlCu), aluminum silicon copper (AlSiCu), molybdenum (Mo), tungsten (W), silver (Ag) or made of any other conductive metal.

In an embodiment of the present disclosure, the material of the bottom electrode layer 170 may include one or more of molybdenum, tungsten, ruthenium, platinum, titanium, aluminum, aluminum copper, aluminum silicon copper, and chromium.

In the embodiment shown in FIG. 2, the acoustic resonator excited in a thickness shear mode further includes a carrier wafer 110. The acoustic mirror 120 is arranged on the carrier wafer 110.

In an embodiment of the present disclosure, the acoustic resonator further includes a bonding auxiliary layer arranged between the carrier wafer 110 and the acoustic mirror 120. In an embodiment of the present disclosure, the bonding auxiliary layer is a thin layer of silicon dioxide.

In an embodiment of the present disclosure, each first acoustic reflective layer is made of low acoustic impedance material, and each second acoustic reflective layer is made of high acoustic impedance material. The low acoustic impedance material may be at least one of silicon dioxide, aluminum, benzocyclobutene (BCB), polyimide or spin on glass, and the high acoustic impedance material may be at least one of molybdenum, tungsten, titanium, platinum, aluminum nitride, tungsten oxide or silicon nitride. It can be understood that in other embodiments, the low acoustic impedance material and the high acoustic impedance material can also use combinations of other materials with a larger impedance ratio.

Each of the first and second acoustic reflective layers of the acoustic mirror 120 may have equal or unequal thicknesses. In an embodiment of the present disclosure, the thickness of the first acoustic reflective layer is positively proportional to a distance between the first acoustic reflective layer and the bottom electrode layer 170, and the thickness of the second acoustic reflective layer is positively proportional to a distance between the second acoustic reflective layer and the bottom electrode layer 170. This design can obtain a larger Q value. Referring to FIG. 4, in the embodiment shown in FIG. 4, the thickness T11 of the first acoustic reflective layer 121 is greater than the thickness T12 of the first acoustic reflective layer 123 which is greater than the thickness T13 of the first acoustic reflective layer 125, and the thickness Th1 of the second acoustic reflective layer 122 is greater than the thickness Th2 of the second acoustic reflective layer 124. It can be understood that in other embodiments, the thickness relationship between each first acoustic reflective layer and the second acoustic reflective layer can also be set according to other rules, such as T11=T12=T13 and Th1=Th2, or T11<T12<T13 and Th1<Th2, or T11<T12, T13<T12, and Th1<Th2.

FIG. 1 also shows the position of the acoustic mirror 120 from the top view. The X direction in FIG. 1 is a propagation direction of the acoustic wave. The bottom electrode layer 170 is formed by patterning, and its width in the Y direction may be the same as or different from (may be larger or smaller) a width of the acoustic mirror 120 in the Y direction. The width (i.e., the dimension in the Y direction in FIG. 1) of the bottom electrode layer 170 is smaller than a spacing between the first common electrode 142 and the second common electrode 144, so that an orthographic projection of the bottom electrode layer 170 on a plane where the top electrode unit is located is between the first common electrode 142 and the second common electrode 144 in the Y direction. In the embodiment shown in FIG. 1, a side of the bottom electrode layer 170 close to the first common electrode 142 in the orthographic projection exceeds an end of each second interdigital electrode 143 close to the first common electrode 142, and a side of the bottom electrode layer 170 close to the second common electrode 144 exceeds an end of each first interdigital electrode 141 close to the second common electrode 144, i.e., the bottom electrode layer 170 is wide enough so that the two sides of its orthographic projection fall outside the second interdigital electrode 143 or the first interdigital electrode 141 respectively.

In the embodiment shown in FIG. 1, the length and width of the bottom electrode layer 170 are larger than those of the acoustic mirror 120, thereby covering the acoustic mirror 120 in both the X direction and the Y direction.

The dimensions in the X direction of the first acoustic reflective layer and the second acoustic reflective layer may be the same or different. In the embodiment shown in FIG. 1, orthographic projections of each first acoustic reflective layer and each second acoustic reflective layer on a plane where the top electrode unit is located exceed the first reflector 152 and the second reflector 154 in the X direction respectively, i.e., the left edge of the orthographic projection falls to the left of the left edge of the first reflector 152, and the right edge falls to the right of the right edge of the second reflector 154.

In the embodiment shown in FIG. 1, orthographic projections of each first acoustic reflective layer and each second acoustic reflective layer on a plane where the bottom electrode layer 170 is located are covered by the bottom electrode layer 170 in the X direction respectively (i.e., the lengths of the first acoustic reflective layer and the second acoustic reflective layer in the X direction are smaller than the length of the bottom electrode layer 170 in the X direction). In another embodiment of the present disclosure, an orthographic projection of each second acoustic reflective layer on the plane where the bottom electrode layer 170 is located exceeds the two sides of the bottom electrode layer 170 in the X direction, i.e., the length of the second acoustic reflective layer in the X direction is greater than the length of the bottom electrode layer 170 in the X direction.

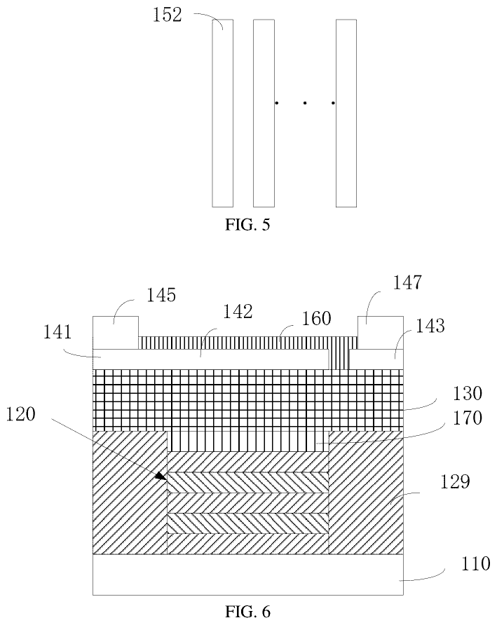

As shown in FIG. 5, electrode strips of the transverse reflectors can be disconnected from one another, or can be connected to one another by a transverse structure as shown in FIG. 1. The electrode strips of the transverse reflectors can be arranged parallel to the fingers of the top electrode unit.

FIG. 6 is a cross-sectional view taken along the line B-B′ in FIG. 1. In this embodiment, the areas of the acoustic mirror 120 and the bottom electrode layer 170 are smaller than the areas of the piezoelectric layer 130 and the carrier wafer 110, so a filling layer 129 is provided around the acoustic mirror 120 and the bottom electrode layer 170. In an embodiment of the present disclosure, a material of the filling layer 129 may include one or more of silicon dioxide, molybdenum, tungsten, tungsten oxide or silicon nitride. In an embodiment of the present disclosure, the material of the filling layer 129 is the same as the material of each first acoustic reflective layer, so as to improve a quality factor of the acoustic resonator.

In the embodiment shown in FIG. 6, the acoustic resonator excited in a thickness shear mode further includes a first metal structure 145 arranged on the first common electrode 141 and a second metal structure 147 arranged on the second common electrode 143. The thicknesses of the first metal structure 145 and the second metal structure 147 are greater than a thickness of the top electrode unit, respectively. The first metal structure 145 and the second metal structure 147 are used for acoustic reflection in the Y direction of FIG. 1.

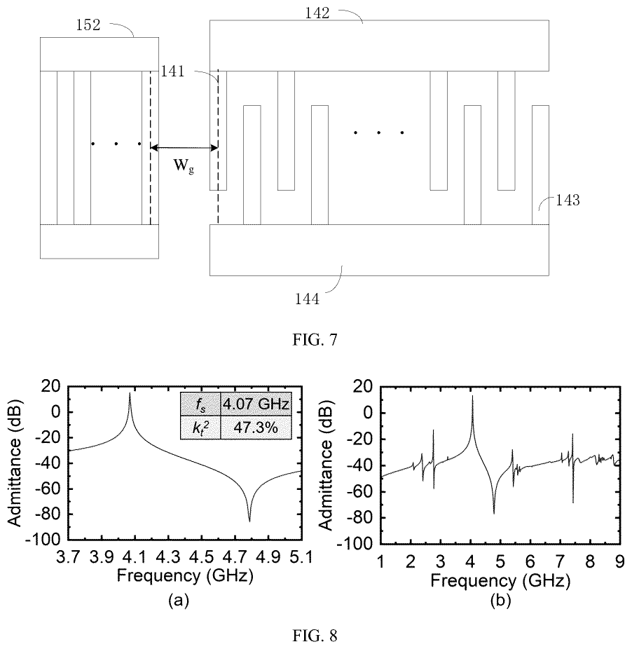

In an embodiment of the present disclosure, a distance Wg (referring to FIG. 7) between the center of an electrode strip closest to the top electrode unit in the first reflector 152 and the center of the interdigital electrode on an edge of the first side of the top electrode unit is equal to ⅛ to 2 wavelengths of the acoustic wave. A distance between the center of the electrode strip closest to the top electrode unit in the second reflector 154 and the center of the interdigital electrode on an edge of the second side of the top electrode unit is equal to ⅛ to 2 wavelengths of the acoustic wave.

A vibration frequency of the mechanical wave in the shear vibration mode formed in the piezoelectric layer 130 is related to the thickness of each film layer and the spacing between adjacent interdigital electrodes in the top electrode unit. A stress is mainly confined to a metal-free area between the first interdigital electrode 141 and the second interdigital electrode 143.

In the embodiment shown in FIG. 6, the acoustic resonator excited in a thickness shear mode further includes a passivation layer 160. The passivation layer 160 is arranged on the piezoelectric layer 130, and covers the first interdigital electrode 141 and the second interdigital electrode 143. The passivation layer 160 can reduce a frequency temperature coefficient of the resonator and passivate the metal electrodes.

FIG. 8 is a simulation result of a characteristic admittance of the acoustic resonator excited in a thickness shear mode according to an embodiment. The curve in the diagram (a) is a part of the curve of in the diagram (b), and kt is the electromechanical coupling coefficient. The characteristic frequency simulation is used to obtain an optimized thickness of the stacked reflector with a resonant frequency of 4.07 GHz. The same characteristic frequency analysis is used to determine a best reflective layer position in the plane and a relative position of the reflective layer stack with respect to the interdigital electrode.

In the description of this specification, reference to the description of the terms “some embodiments”, “other embodiments”, “ideal embodiments”, etc. means that a particular feature, structure, material or feature described in connection with the embodiment or example is included in the present specification at least one embodiment or example of the disclosure. In this specification, schematic descriptions of the above terms do not necessarily refer to the same embodiment or example.

The technical features in the above embodiments can be combined arbitrarily. For concise description, not all possible combinations of the technical features in the above embodiments are described. However, all the combinations of the technical features are to be considered as falling within the scope described in this specification provided that they do not conflict with each other.

The above-mentioned embodiments only describe several implementations of the present disclosure, and their description is specific and detailed, but should not be understood as a limitation on the patent scope of the present disclosure. It should be pointed out that for those skilled in the art may further make variations and improvements without departing from the conception of the present disclosure, and these all fall within the protection scope of the present disclosure. Therefore, the protection scope of the present disclosure should be subject to the appended claims.

1. An acoustic resonator excited in a thickness shear mode, comprising:
an acoustic mirror comprising at least one first acoustic reflective layer and at least one second acoustic reflective layer, acoustic impedance of each first acoustic reflective layer being less than the acoustic impedance of each second acoustic reflective layer;
a bottom electrode layer arranged on the acoustic mirror;
a piezoelectric layer arranged on the bottom electrode layer, the piezoelectric layer comprising at least one of single crystal lithium niobate or single crystal lithium tantalate;
a top electrode unit arranged on the piezoelectric layer; and
transverse reflectors arranged on the piezoelectric layer, the transverse reflectors comprising a first reflector arranged on a first side of the top electrode unit and a second reflector arranged on a second side of the top electrode unit, the first side and the second side being opposite sides, and the transverse reflectors being configured to transversely reflect an acoustic wave;
wherein the bottom electrode layer and the top electrode unit are configured to apply an electric field.

2. The acoustic resonator excited in a thickness shear mode according to claim 1, wherein a direction of the electric field formed by the bottom electrode layer and the top electrode unit is substantially the same as a thickness direction of the piezoelectric layer, and the bottom electrode layer and the top electrode unit are further configured to generate a shear mode mechanical wave across a thickness of the entire piezoelectric layer.

3. The acoustic resonator excited in a thickness shear mode according to claim 1, wherein a thickness of the first acoustic reflective layer is positively proportional to a distance between the first acoustic reflective layer and the bottom electrode layer, and a thickness of the second acoustic reflective layer is positively proportional to a distance between the second acoustic reflective layer and the bottom electrode layer.

4. The acoustic resonator excited in a thickness shear mode according to claim 1, wherein the acoustic mirror comprises three layers of the first acoustic reflective layer and two layers of the second acoustic reflective layer, and the first acoustic reflective layer and the second acoustic reflective layer in the acoustic mirror are arranged alternatively.

5. The acoustic resonator excited in a thickness shear mode according to claim 1, wherein a material of the first acoustic reflective layer comprises at least one of silicon dioxide, aluminum, benzocyclobutene, polyimide or spin on glass, and a material of the second acoustic reflective layer comprises at least one of molybdenum, tungsten, titanium, platinum, aluminum nitride, tungsten oxide or silicon nitride.

6. The acoustic resonator excited in a thickness shear mode according to claim 1, wherein the top electrode unit comprises a first common electrode, a second common electrode, a plurality of first interdigital electrodes and a plurality of second interdigital electrodes, each of the first interdigital electrodes is electrically connected to the first common electrode, each of the second interdigital electrodes is electrically connected to the second common electrode, any of the first interdigital electrodes is insulated from any of the second interdigital electrodes.

7. The acoustic resonator excited in a thickness shear mode according to claim 6, further comprising a passivation layer arranged on the piezoelectric layer, the passivation layer covering each of the first interdigital electrodes and each of the second interdigital electrodes.

8. The acoustic resonator excited in a thickness shear mode according to claim 6, wherein a direction of a connecting line between the transverse reflectors on both sides of the top electrode unit is the same as a propagation direction of the acoustic wave, a width of the bottom electrode layer is smaller than a spacing between the first common electrode and the second common electrode, so that an orthographic projection of the bottom electrode layer on a plane where the top electrode unit is located is between the first common electrode and the second common electrode, and orthographic projections of each of the first acoustic reflective layers and each of the second acoustic reflective layers on the plane exceed the first reflector and the second reflector in the direction of the connecting line, respectively.

9. The acoustic resonator excited in a thickness shear mode according to claim 6, wherein the first reflector and the second reflector both comprise at least one electrode strip, a distance between the center of an electrode strip closest to the top electrode unit in the first reflector and the center of the interdigital electrode on an edge of the first side of the top electrode unit is equal to ⅛ to 2 wavelengths of the acoustic wave, and a distance between the center of the electrode strip closest to the top electrode unit in the second reflector and the center of the interdigital electrode on an edge of the second side of the top electrode unit is equal to ⅛ to 2 wavelengths of the acoustic wave.

10. The acoustic resonator excited in a thickness shear mode according to claim 6, further comprising a first metal structure arranged on the first common electrode and a second metal structure arranged on the second common electrode, wherein thicknesses of the first metal structure and the second metal structure are greater than a thickness of the top electrode unit respectively, the first metal structure and the second metal structure are used for acoustic reflection in a second direction, and the second direction is perpendicular to a propagation direction of the acoustic wave.

11. The acoustic resonator excited in a thickness shear mode according to claim 1, wherein an orthographic projection of each of the second acoustic reflective layers on a plane where the bottom electrode layer is located exceeds two sides of the bottom electrode layer in a first direction, or orthographic projections of each of the first acoustic reflective layers and each of the second acoustic reflective layers on the plane where the bottom electrode layer is located are covered by the bottom electrode layer respectively;
wherein the first direction is parallel to a propagation direction of the acoustic wave.

12. The acoustic resonator excited in a thickness shear mode according to claim 1, wherein a material of the top electrode unit is the same as the material of the transverse reflectors and is at least one of a metal or a metallic alloy.

13. The acoustic resonator excited in a thickness shear mode according to claim 1, wherein one of the at least one first acoustic reflective layer is closer to the bottom electrode layer than all of the second acoustic reflective layers.

14. The acoustic resonator excited in a thickness shear mode according to claim 1, further comprising a carrier wafer, wherein the acoustic mirror is arranged on the carrier wafer.

15. The acoustic resonator excited in a thickness shear mode according to claim 14, further comprising a bonding auxiliary layer arranged between the carrier wafer and the acoustic mirror.
